(19) United States
(12) Patent Application Publication
(10) Pub. No.: US 2013/0151182 A1
(43) Pub. Date: Jun. 13, 2013

(54) PROCESS FOR SUPPLYING A MEDICAL DEVICE

(71) Applicant: Klaus GLINDEMANN, Stockelsdorf (DE)

(72) Inventor: Klaus GLINDEMANN, Stockelsdorf (DE)

(73) Assignee: Dräger Medical GmbH, Lubeck (DE)

(21) Appl. No.: 13/483,189

(22) Filed: May 30, 2012

(30) Foreign Application Priority Data
Dec. 10, 2011 (DE) 10 2011 120 891.0

(51) Int. Cl. G01R 31/36

(52) U.S. Cl. 702/63

(57) ABSTRACT

A process for supplying a medical device (4), in which at least one battery (5) is supplied with energy, wherein the batteries (5) undergo a calendar-based and/or cycle-dependent aging. The utilization time of the batteries (5) in the medical device (4) is prolonged beyond the conventional replacement periods both within the framework of interruption-free power supply and in mobile use. Provisions are made for determining a remaining calendar-based life of the battery (5) from the difference of the total life of the battery (5) and the operating time of the battery (5) and/or for determining a remaining cycle-dependent life of the batteries (5) from the product of the operating time of the batteries (5) by the ratio of the remaining capacity of the battery (5) to the discharged capacity of the battery (5).

### CROSS REFERENCE TO RELATED APPLICATIONS

This application claims the benefit of priority under 35 U.S.C. §119 of German Patent Application DE 10 2011 120 891.0 filed Dec. 10, 2011, the entire contents of which are incorporated herein by reference.

### FIELD OF THE INVENTION

The present invention pertains to a process for supplying a medical device, in which at least one battery is supplied with energy, wherein the batteries undergo calendar-based and/or cycle-dependent aging.

### BACKGROUND OF THE INVENTION

Medical devices, which are supplied with electric energy from the power grid, additionally also contain batteries in order to be able to continue to be operated in case of an interruption in the grid. The batteries will then supply the electric energy needed during the interruption. The operating time of the batteries without supply from the grid is limited by the consumption of the medical device and of the energy stored in the batteries. The batteries are used only slightly actively in this mode of operation, because grid interruption is the exception of supply from the grid.

Mobile use is a further application for the use of batteries in medical devices. The supply from an electric supply grid is eliminated in connection with a mobile use of the batteries, and the batteries supply the electric energy exclusively. The operating time without supply from the grid is limited by the consumption of the medical device and of the energy being sorted in the batteries. The batteries are used highly actively in this mode of operation, because mobile use requires many charging and discharging cycles.

Preservation of the function and hence also the knowledge of the expectable life and of the aging properties of a battery are of crucial significance in case of both mobile use and use during an interruption in the electric supply grid. Aging and battery life are distinguished here as cycle life and calendar-based life. The cycle life is affected by all the mechanisms that cause a battery to age based on the loading thereof during the operation, i.e., mainly charging and discharging cycles, a certain frequency and depth of discharge. The cycle life consequently indicates how many charging and discharging cycles are possible for a battery before the latter stops functioning. Besides the pure number of cycles and the type of the particular cycles, especially the depth to which the battery is discharged and to which it is recharged is relevant here.

By contrast, calendar-based aging describes the aging that also occurs when the battery is not loaded at all. Calendar-based aging and cycle-dependent aging may superimpose each other, and calendar-based aging or cycle-dependent aging is the determining factor depending on the use of the battery.

To guarantee reliable supply of the medical device with electric energy, replacement of the batteries after a certain time is also of fundamental significance, besides the preservation of the function of the batteries. The point of time of replacement, i.e., the period between replacements, has been defined hitherto as a fixed time based on experience with the operation of the medical devices in worldwide use. The definition of a battery replacement period in medical devices has to take into account all relevant applications, so that unfavorable factors occurring accidentally also affect the length of the replacement period and shorten same.

However, this common practice leaves out of consideration the fact that measurements on batteries after the end of utilization in the medical device, i.e., at the end of the replacement period, have revealed that not all batteries are used up. However, the replacement of functional batteries represents a waste of resources and increasingly also harm to the environment, because the batteries usually must be disposed of.

### SUMMARY OF THE INVENTION

Based on the acknowledged state of the art as well as the drawbacks shown, an object of the present invention is therefore to improve a process of the type described in the introduction such that the utilization time of batteries in medical devices is prolonged beyond the conventionally assumed replacement periods both within the framework of uninterrupted power supply and in mobile use.

According toe the invention a process is provided for supplying a medical device, the process comprises the steps of supplying a battery with energy, wherein the battery undergoes a calendar-based and/or cycle-dependent aging.

According to one aspect of the process, a remaining calendar-based life of the battery is determined from a difference between an overall life of the battery and an operating time of the battery.

According to one aspect of the process, in case the battery undergoes a cycle-dependent aging, a remaining cycle-dependent life of the battery is determined from a product of the operating time of the battery by the ratio of the remaining capacity Cᵣₑₛₜ of the battery to the discharged capacity C_{discharged} of the battery.

A basic idea is to prolong the period between battery replacements by a remaining calendar-based or cycle-dependent life.

Besides the time lapse, which affects the calendar-based life, further factors may come up, which affect the calendar-based life of the battery. The temperature has proved to be an essential influential factor. In addition, investigations have revealed that the temperature dependence of a manufacturer-specific life of a battery is described by a logarithmic function. A time, which corresponds to the life of the battery, can thus be unambiguously assigned to the temperature of a battery. The calendar-based life of a battery is thus a manufacturer-specific variable, which may vary from one battery to the next.

A detailed documentation of the relationship between calendar-based life as well as time and temperature can be found, e.g., in the reference “Panasonic Value Regulated Lead-Acid Batteries Technical Handbook 2007, Chapter 3.”

Since the temperature may change depending on the location of the medical device, the mean temperature of the battery is preferably used, which is obtained from the averaging of the local temperatures in case of the non-stationary use of the battery. The calculation of the mean temperature Tₘₑₐₙ is thus obtained according to the following equation:

Tₘₑₐₙ=Tₛᵤₘ/n_{T}.

In this equation, Tₛᵤₘ represents the summed-up temperature values, whereas n_{T} indicates the number of temperature values determined.

To determine the service life of the battery within the framework of calendar-based monitoring, it is advantageous to determine the difference between the current time t_{today} and the point in time at which battery operation starts, tₛₜₐᵣₜ, according to the equation

t_{operating time}=t_{today}−tₛₜₐᵣₜ.

The remaining calendar-based life tᵣₑₛₜ of the battery is then obtained from the difference of the manufacturer-specific life t_{life} of the battery and the operating time t_{operating time} of the battery according to the equation

tᵣₑₛₜ=t_{life}−t_{operating me}.

The remaining cycle-dependent life of the battery is obtained, by contrast, from the extrapolation of the previous use of the batteries up to this point in time taking into account the still available capacity, i.e., from the product of the operating time t_{operating time} of the battery by the ratio of the remaining capacity Cᵣₑₛₜ to the discharged capacity C_{discharged} according to the equation

tᵣₑₛₜ=t_{operating time}×Cᵣₑₛₜ/Cₜₒₜₐₗ.

This extrapolation presupposes continuous use of the battery by the user. The operating time t_{operating time} is obtained from the difference of the current point in time t_{today} and the point in time tₛₜₐᵣₜ at which the battery operation starts in this case as well.

The remaining capacity Cᵣₑₛₜ results again from the difference of the total capacity and the discharged capacity according to equation

Cᵣₑₛₜ=Cₜₒₜₐₗ−C_{discharged}.

The total capacity Cₜₒₜₐₗ is the capacity that the battery can discharge during the manufacturer-specific, cycle-dependent service life of the battery. A detailed documentation of the influential variables and calculation of the total capacity can likewise be found in the reference “Panasonic Value Regulated Lead-Acid Batteries Technical Handbook 2007, Chapter 3.”

To check how far a battery being used in the medical device can still be used further, it is advantageous to compare the remaining calendar-based life and/or the remaining cycle-dependent life with a time period, which indicates the distance in time between the start of battery operation and battery replacement. If the remaining calendar-based or cycle-dependent life is sufficient for a further time period intended for the battery replacement, the batteries are not replaced yet and are used further.

According to another aspect of the invention, a medical system is provided comprising a battery, a medical device with a current and a voltage sensor, the battery being connected to the medical device, and a power supply supplying the battery with energy. The battery undergoes a calendar-based and/or cycle-dependent aging. A remaining life processor is provided which determines at least one of:
a remaining calendar-based life of the battery from a difference between a calendar-based life of the battery and an operating time of the battery; and
a remaining a remaining cycle-dependent life of the battery from the product of the operating time of the battery by the ratio of the remaining capacity of the battery to the discharged capacity of the battery.

Moreover, the present invention provides for a device for carrying out the process, wherein the device or system provided with the battery and with the medical device also has a current and voltage sensor in addition to a temperature sensor. Both the current and voltage sensor and the temperature sensor are associated with a data recorder.

The present invention will be explained in more detail below on the basis of the drawings. The various features of novelty which characterize the invention are pointed out with particularity in the claims annexed to and forming a part of this disclosure. For a better understanding of the invention, its operating advantages and specific objects attained by its uses, reference is made to the accompanying drawings and descriptive matter in which preferred embodiments of the invention are illustrated.

### BRIEF DESCRIPTION OF THE DRAWINGS

FIG. 1 is a block diagram of the system and process according to the present invention.

### DESCRIPTION OF THE PREFERRED EMBODIMENTS

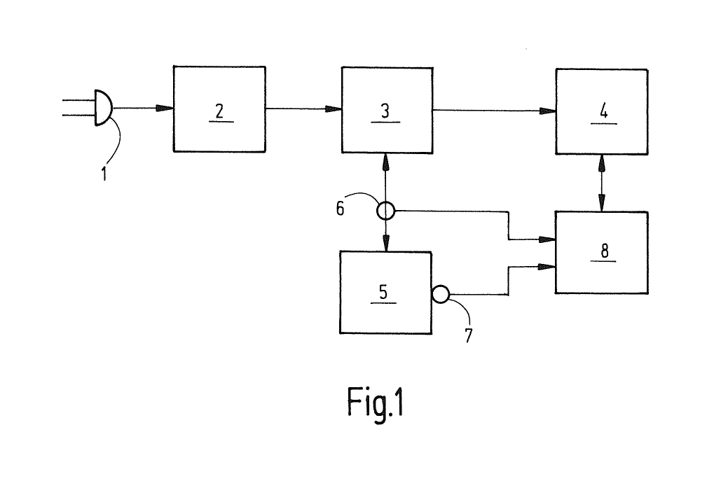

Referring to the drawings in particular, the process and system shown in FIG. 1 is used to determine a calendar-based aging as well as a cycle-dependent aging from the history of the batteries 5 in order to estimate the remaining calendar-based life and the remaining cycle-dependent life during comparable use from the determined calendar-based aging and the determined cycle-dependent aging as well as from the life of the battery 5 specified by the manufacturer. The remaining calendar-based life and the remaining cycle-dependent life are then compared with the duration of the service period. The service period indicates the maximum point in time for testing as well as checking and for a replacement of the batteries 5, which may possibly accompany this. If the time values determined for the calendar-based and cycle-dependent life are still sufficient for another service period, the batteries 5 are not replaced yet.

The blocks shown in FIG. 1 are functional modules, which do not necessarily have to correspond to separate physical assembly units. An individual functional module could rather be embodied by a plurality of physical assembly units. Furthermore, it would be possible to embody a plurality of functional modules with an individual physical component.

The process shown in FIG. 1 can be divided into two process variants.

The first variant, which provides for the operation of the medical device 4 with supply from the grid, begins with the power pack (power supply) 2 being supplied with electric energy via the grid connection 1. The power pack 2 is connected to the medical device 4 by a feed line, in which the battery charging device and switch 3 are arranged. To make it possible to continue to supply the medical device 4 with electric energy in case of a grid interruption, the batteries 5 supply the electric energy for the medical device 4 during the grid interruption. The batteries 5 undergo a calendar-based aging in this process variant, i.e., the determining factors, which affect the aging of the batteries 5, are the time and temperature. To determine the remaining calendar-based life within the framework of the process according to the present invention, the batteries 5 are introduced into the medical device 4 at first in an unused state at the beginning of the process, and the current date as well as the current time of day are stored in the data recorder 8, which is associated with the medical device 4 and the batteries 5. These initial points in time represent the start of the service period.

Moreover, a temperature sensor 7, which records the mean temperature of the batteries 5 in the known manner, is associated with the batteries 5. The mean temperatures measured are included in the calculation of the calendar-based life. A specification provided by the manufacturer of the batteries 5 is available for this in the form of a functional dependence, by means of which the calendar-based life can be determined in the conventional manner.

The electric energy that can still be supplied by the batteries 5 for the medical device 4 can be determined by means of a current and voltage sensor 6, which is likewise associated with the batteries 5, in a conventional and known manner, namely, by measuring the charge capacity that has flown through.

Based on the operating time of the batteries 5, which results from the difference between the stored starting points in time and the current time, as well as the calendar-based life specified by the manufacturer of the batteries 5, whose calculation includes the mean temperature measured by means of the temperature sensor 7, the remaining calendar-based life can be determined from the difference between the calendar-based life and the operating time of the batteries 5.

In another variant of the process according to the present invention, which is used for the mobile use of the batteries 5 and is employed to determine the cycle-dependent life, the previous operating time of the batteries 5 is extrapolated taking into account the still available capacity of the batteries 5.

The operating time of the batteries 5 as well as the remaining capacity of the batteries 5 and the discharged capacity 5 are determined for this. The remaining capacity of the batteries 5 is obtained here from the total capacity of the batteries 5 specified by the manufacturer of the batteries 5 and the capacity of the batteries 5 that had already been discharged. To measure the capacity of the batteries 5 that had already been discharged, the current and voltage sensor associated with batteries 5, which measures the charge flux of the batteries 5 and the duration of discharge in the manner known per se, is used here as well. The measured data are stored in data recorder 8. The battery charging device and switch 3 ensure the cycling, i.e., the charging and discharging of the batteries 5, and the connection between batteries 5 and medical device 4.

The embodiment of the present invention is not limited to the exemplary embodiment described above. A number of variants are rather conceivable, which make use of the solution described in other types of embodiments as well. For example, the remaining calendar-based and cyclic lives can be measured simultaneously.

While specific embodiments of the invention have been shown and described in detail to illustrate the application of the principles of the invention, it will be understood that the invention may be embodied otherwise without departing from such principles.

What is claimed is:

1. A process for supplying a medical device, the process comprising the steps of:
supplying a battery with energy, wherein the battery undergoes a calendar-based and/or cycle-dependent aging;
determining a remaining calendar-based life of the battery from a difference between a calendar-based life of the battery and an operating time of the battery.

2. A process in accordance with claim 1, wherein the remaining calendar-based life is compared with a time period, which describes a time between a start of operation of the battery and a replacement of the battery.

3. A process in accordance with claim 1, wherein a mean temperature of the battery is determined.

4. A process for supplying a medical device, the process comprising the steps of:
supplying a battery with energy, wherein the battery undergoes a calendar-based and/or cycle-dependent aging;
determining a remaining a remaining cycle-dependent life of the battery from the product of the operating time of the battery by the ratio of the remaining capacity of the battery to the discharged capacity of the battery.

5. A process in accordance with claim 4, wherein the remaining cycle-dependent aging is compared with a time period, which describes a time between a start of operation of the battery and a replacement of the battery.

6. A process in accordance with claim 4, wherein a remaining capacity of the battery is determined from a difference of the total capacity of the battery and the discharged capacity of the battery.

7. A medical system comprising:
a battery;
a medical device with a current and a voltage sensor, said battery being connected to said medical device;
a power supply supplying said battery with energy, wherein said battery undergoes a calendar-based and/or cycle-dependent aging;
a remaining life processor determining at least one of:
a remaining calendar-based life of the battery from a difference between a calendar-based life of the battery and an operating time of the battery; and
a remaining a remaining cycle-dependent life of the battery from the product of the operating time of the battery by the ratio of the remaining capacity of the battery to the discharged capacity of the battery.

8. A device in accordance with claim 7, further comprising a temperature sensor.

9. A device in accordance with claim 7, further comprising a data recorder connected to said remaining life processor, said current and voltage sensor being operatively connected to said data recorder.

10. A device in accordance with claim 8, further comprising a data recorder connected to said remaining life processor, wherein said temperature sensor is operatively connected to said data recorder.
